(19) United States
(12) Patent Application Publication
(10) Pub. No.: US 2004/0063039 A1
(43) Pub. Date: Apr. 1, 2004

(54) Method for inductor trimming of the high frequency integrated passive devices

(75) Inventors: Shang-Yu Liang, Hsinchu (TW); Shu-Hui Tsai, Hsinchu (TW); Chun-Hsien Lee, Hsinchu (TW); Chung-Hsien Lin, Hsinchu (TW)

Correspondence Address: BRUCE H. TROXELL, SUITE 1404, 5205 LEESBURG PIKE, FALLS CHURCH, VA, 22041, US

(73) Assignee: ASIA PACIFIC MICROSYSTEMS, INC.

(21) Appl. No.: 10/464,495

(22) Filed: Jun. 19, 2003

(30) Foreign Application Priority Data
Oct. 1, 2002 (TW) 091122607

(51) Int. Cl. G03F 7/16; G03F 7/20; G03F 7/40

(52) U.S. Cl. 430/312; 430/314; 430/315; 430/319; 430/316; 430/318

(57) ABSTRACT

Disclosed herein is a method for inductor An Improved Structure For the Endpiece of Tape Rule of the high frequency integrated passive devices in which a spiral inductor pattern is formed on an insulation substrate, the spiral inductor pattern is spirally coiled outwards from the center. A thick film dielectric layer made of bisbenzocyclobutene (BCB) is formed on the spiral inductor pattern. A metal layer can be formed according to under bump metallization technique (UBM). The metal layer is either formed into a continuous spirally coiled form or a spread discrete configuration. With this structure, laser trimming can be applied to the metal layer pattern so as to acquire an ideal inductance value, thereby achieving wafer level trimming and compensating the process tolerance.

### BACKGROUND OF THE INVENTION

1. Field of the Invention

The present invention relates to a method for inductor trimming of a high frequency integrated passive devices. In particular, to a method for inductor trimming of a high frequency passive devices wherein an ideal inductance value can be attained by means of laser trimming for trimming the metal pattern covered on the inductor of the insulation substrate.

2. Description of the Prior Art

A spirally coiled electrode pattern formed on a semiconductor substrate using photo plate printing or other resembling thick film printing methods for serving as an inductance component in a semiconductor circuit is quite well known to those who are skilled in the art.

In the thick film printing method, a photo mask having a plurality of via holes for a required pattern is used to shade the upper surface of an insulation substrate, and an electrically conducting paste is coated on the photo mask such that the required pattern may be provided with a relatively thicker conducting material formed on the upper surface of the insulation substrate, and the photo mask is completed by exposing its via holes.

In a photo plate printing method, a relatively thin conducting film is substantially formed on the entire upper surface of an insulation substrate, afterwards, an anti-corrosion agent (such as a photo sensitive resin or the like) is substantially formed on the entire conducting thin film by means of spin coating or printing. Further to this, the upper surface of the anti-corrosion thin film is shaded by the thin film of a photo mask having a prescribed pattern, and the required portion of the anti-corrosion thin film is hardened by the radiation of infrared ray or the like. Then afterwards, the anti-corrosion thin film is lifted off but the hardened portion is preserved. The exposed portion of the conducting film is removed so as to form a conductor having a desired pattern. Finally the hardened portion of the anti-corrosion thin film is removed.

In another photo plate printing method, the thin film of a photo mask having a prescribed pattern is formed by coating a photo sensitive and conducting paste on the upper surface of an insulation substrate, then the photo sensitive and conducting paste layer is shaded—and exposed—later so as to develop an image.

It will be understood that the techniques for forming an inductor pattern on a substrate have been a matured prior art for a long time. Owing to the fact that inductance value is important to impedance matching or frequency filtering, and in addition, the increasing needs of microminiaturizing electronic components, the trimming of inductance has already been playing an important role on the electronic technology.

U.S. Pat. No. 6,005,466 is cited, as illustrated in FIG. 1, in which a metallic structure 12 was applied on an inductor pattern 11 by flip chip solder bonding technique so as to produce an image inductance 13, then afterwards, the image inductance were modified by laser trimming so as to attain the ideal inductance value.

However, in the above-cited case, the cost of flip chip solder bonding process is very high, and its immature technique will result the quality of the product become poor and uneconomical.

### SUMMARY OF THE INVENTION

Accordingly, it is an object of the present invention to provide a method for inductor trimming of the high frequency integrated passive devices in which laser trimming can be directly applied 10 trim the metal layer pattern which is directly formed on the upper surface of a thick film dielectric layer intercalated between said metal layer and a spiral inductor pattern.

It is another object of the present invention to provide a method for trimming high frequency inductor of a passive component in which wafer level trimming can be performed by directly forming a dielectric layer and a metal layer pattern on the upper surface of an inductor pattern so as to enable to carry out wafer level trimming and on wafer measurement feedback thereby available for both coarse and fine trimming and also causing possibility for better process tolerance.

To achieve the above-mentioned objects, in the present invention, the dielectric layer formed on the upper surface of the spiral inductor pattern may be a thick film layer of bisbenzocyclobutene (BCB), polyimide, photoresist materials such as SU8, SiO₂, Si₃N₄, and SiOₓN_{y}, or silicon glass materials (PSG), borophosphosilicate glass (BPSG), fluorinated silicate glass (FSG), or other materials with low dielectric constant such as SiLK. Besides, the metal layer pattern formed on the dielectric layer may be made of a common metallic material, or a metal layer formed according to under bump metallization (UBM) technique.

For fully understanding of the nature, objects and advantages of the invention, reference should be made to the following detailed descriptions taken in conjunction with the accompanying drawings.

### BRIEF DESCRIPTION OF THE DRAWINGS

FIG. 1 is a schematic view showing the method for trimming high frequency inductor disclosed by U.S. Pat. No. 6,005,466.

FIG. 2 is a cross discrete view of the present invention.

FIG. 3 is a fragmentarily enlarged view of FIG. 2.

FIG. 4 is a schematic view of the spiral inductor pattern of the present invention.

FIG. 5 is a schematic view of another spiral inductor pattern of the present invention.

FIG. 6 is a schematic view of the metal layer pattern in a first embodiment.

FIG. 7 is a schematic view of the metal layer pattern in a second embodiment.

FIG. 8 is a schematic view of the metal layer pattern in a third embodiment.

FIG. 9 is a schematic view of the metal layer pattern in a fourth embodiment.

FIG. 10 is a schematic view of the metal layer pattern in a fifth embodiment.

FIG. 11 is a schematic view of the metal layer pattern in a sixth embodiment.

FIG. 12 is a schematic view of the metal layer pattern in a seventh embodiment.

FIG. 13 is a schematic view of the metal layer pattern in an eighth embodiment.

FIG. 14 is a schematic view of the metal layer pattern in a ninth embodiment.

FIG. 15 is a schematic view of the metal layer pattern in a tenth embodiment.

FIG. 16 is a schematic view of the metal layer pattern in an eleventh embodiment.

FIG. 17 is a schematic view of the metal layer pattern in a twelfth embodiment.

FIG. 18 is a schematic view of the square spiral inductor of the present invention.

FIG. 19 is a graph showing the relationship of the measurement result between the trimming areas of the metal layer pattern and the inductance value (nH) according to the present invention.

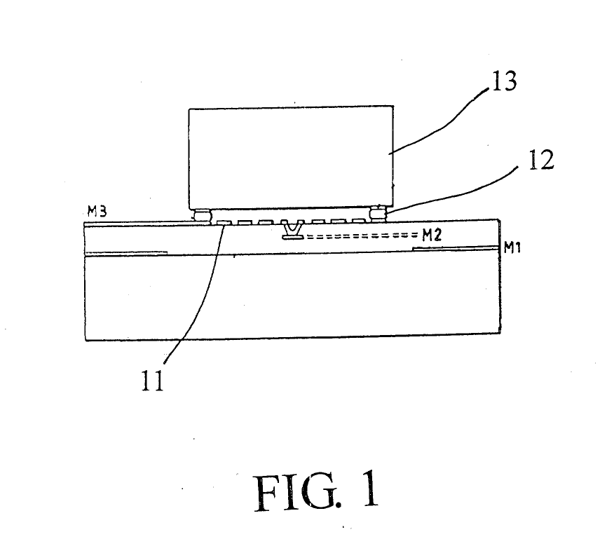

### DETAILED DESCRIPTION OF THE PREFERRED EMBODIMENTS

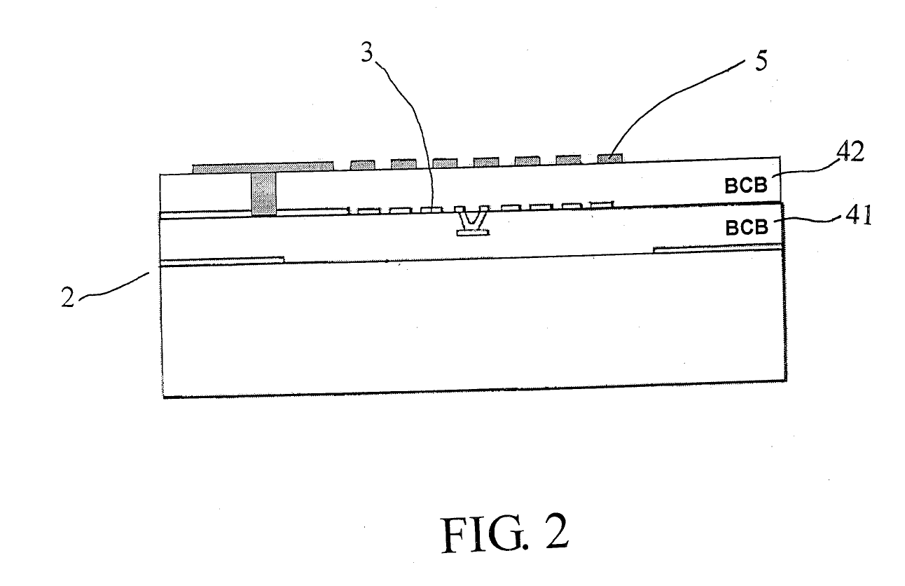

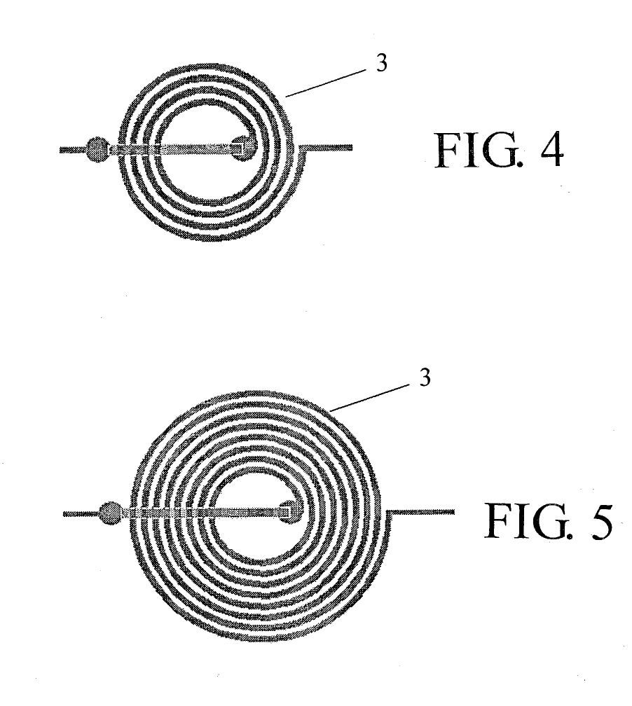

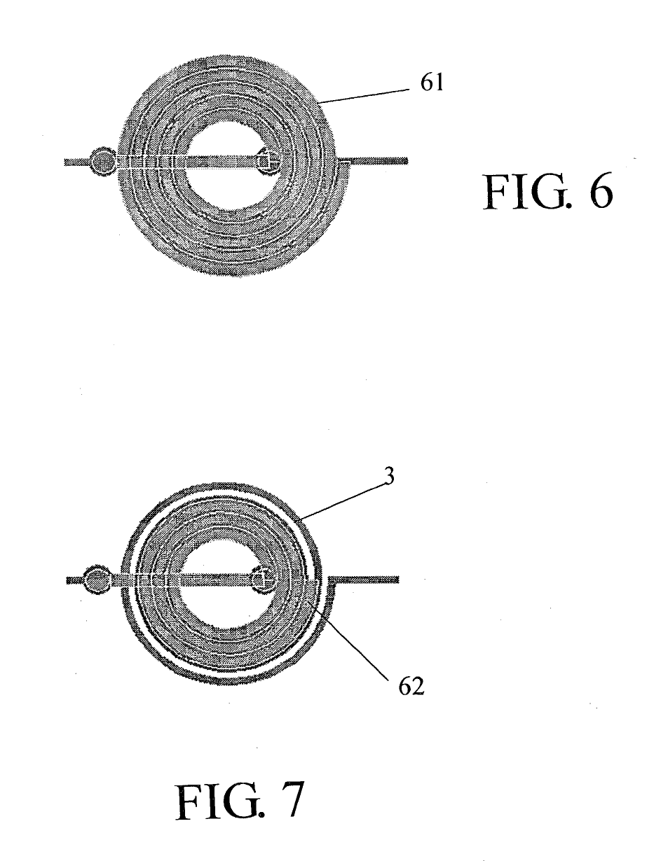

As shown in FIG. 2, in the present invention, dielectric layers 41, 42, are formed of thick BCB film, and a spiral inductor pattern 3 formed on an insulation substrate 2 is formed of an approximately 5 μm thick copper spirally coiled outwards from the center (see FIGS. 4, 5). The second thick BCB film dielectric layer 42 is formed on the first thick BCB film dielectric layer 41. An electrode is downward extended from one end of the second dielectric layer 42 and is stretched out from the first-dielectric layer 41. Besides, a metal layer pattern 5 is formed on the upper surface of the second dielectric layer 42. The metal layer pattern 5 is formed in a continuously coiled, or in a spread manner tracing the track of the inductor pattern as shown in following successive FIGS. 6 to 17. With this structure, laser trimming of the inductor can be directly applied to the pattern 5.

Other than thick bisbenzocyclobutene (BCB) film, the dielectric layers 41, 42 can be formed of thick films of other materials such as polyimide, photoresist materials such as SUB, SU8, SiO₂, Si₃N₄, and SiOₓN_{y}, or various silicon glass materials (PSG), borophosphosidlicate glass (BPSG), fluorinated silicate glass (FSG), borophosphosilicate glass (BPSG), fluorinated silicate glass (FSG), or other dielectric layer of low dielectric constant such as SiLK.

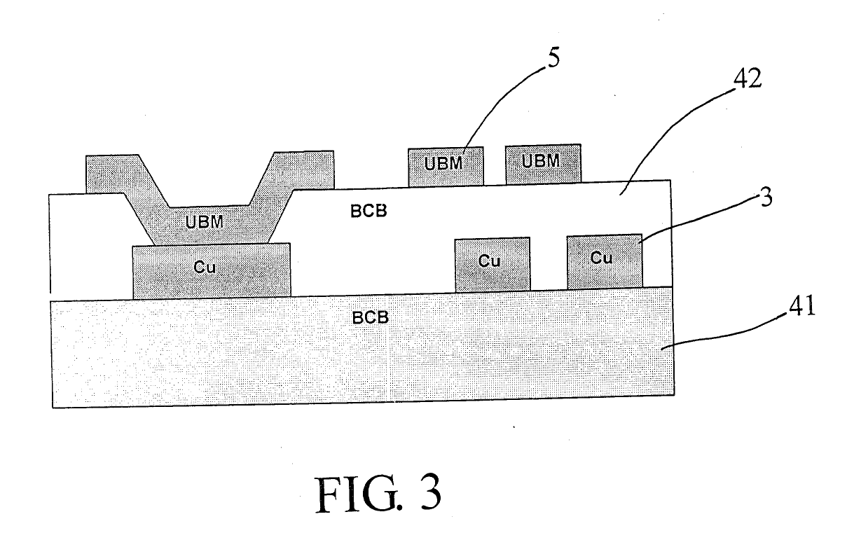

Referring to FIG. 3, the metal layer pattern 5 may be formed according to bump metallization (UBM) technique. Now this under bump metal layer is used to represent the metal layer pattern formed according to said technique.

In the present invention, various forms of design are provided for forming a metal layer on the upper surface of the second thick BCB film dielectric layer 42 for trimming the inductor by laser trimming.

In the first embodiment shown in FIG. 6, a metal layer pattern 61 is formed in a continuous manner similar to that of the spiral inductor pattern 3 mentioned above, and is formed in a mode completely shading the entire spiral inductor pattern 3.

In the second embodiment shown in FIG. 7, a metal layer pattern 62 is formed in a donut configuration within the inmost loop of the spiral inductor pattern 3.

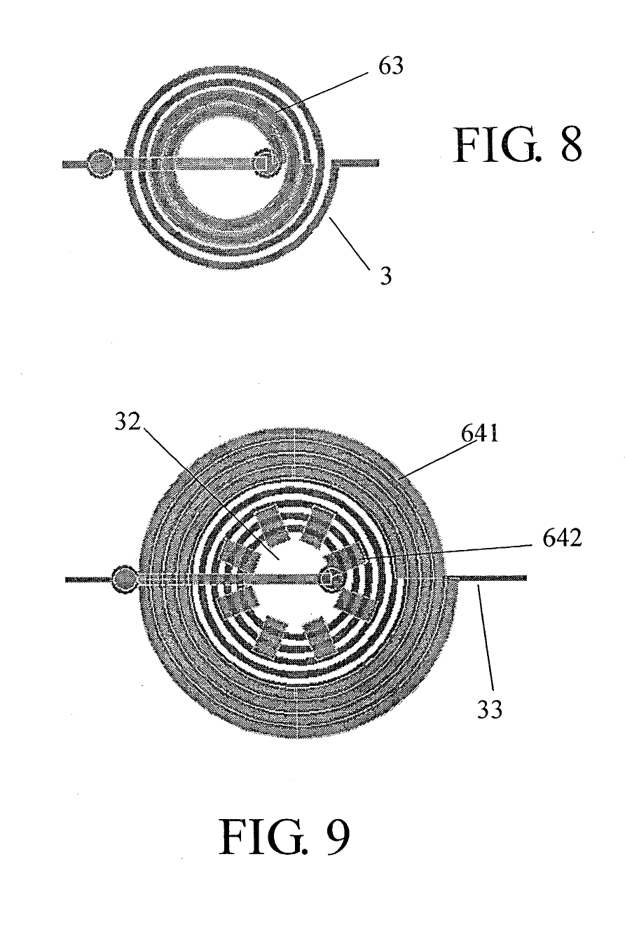

In the third embodiment shown in FIG. 8, a metal layer pattern 63 is formed according to partial portion of the spiral inductor pattern 3, and its conductor width is larger than that of the pattern 3 so that it is able to shade the conductor of the spiral inductor pattern 3.

In the fourth embodiment shown in FIG. 9, outer part of a metal layer pattern is formed in a continuous spirally coiled pattern 641 overlapping the corresponding outer portion of the spiral inductor pattern 3; while the inner part of the metal layer pattern is formed into a discrete metal layer pattern 642 composed of several small blocks spread in an annular configuration. Part of the discrete metal layer pattern 642 is extended to the center area 31 of the spiral inductor pattern 3.

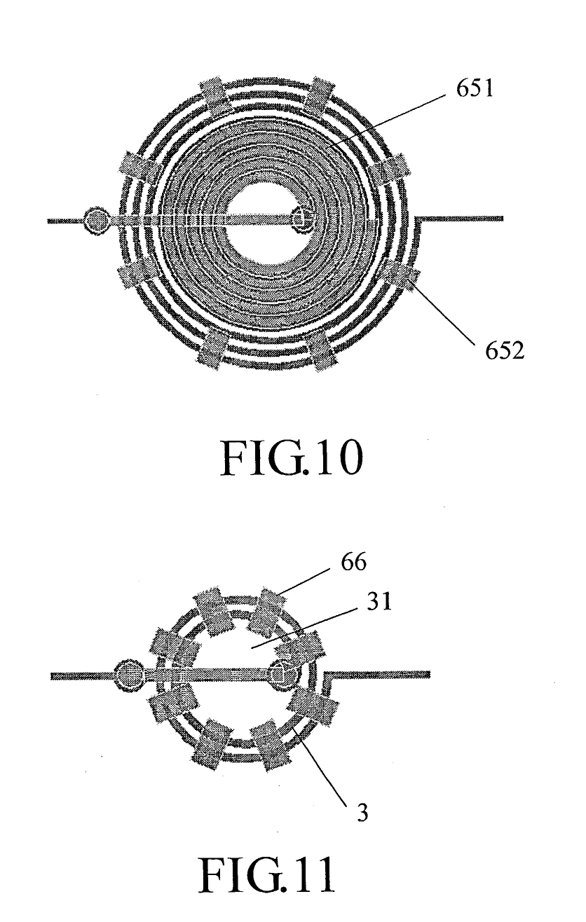

In the fifth embodiment shown in FIG. 10, on the contrary to FIG. 9, inner part of a metal layer pattern is formed in a continuous spirally coiled pattern 651 overlapping the corresponding inner portion of the spiral inductor pattern 3, while the outer part of the metal layer pattern is formed into a discrete metal layer pattern 652 composed of several small blocks spread in an annular configuration.

In the sixth embodiment shown in FIG. 11, a discrete metal layer pattern 66 is spread on the spiral inductor pattern 3 in an annular configuration, and is widely shading the inner and outer loops of the pattern 3. Besides the discrete metal layer pattern 66 is partially extended to the center area 31 of the spiral inductor pattern 3.

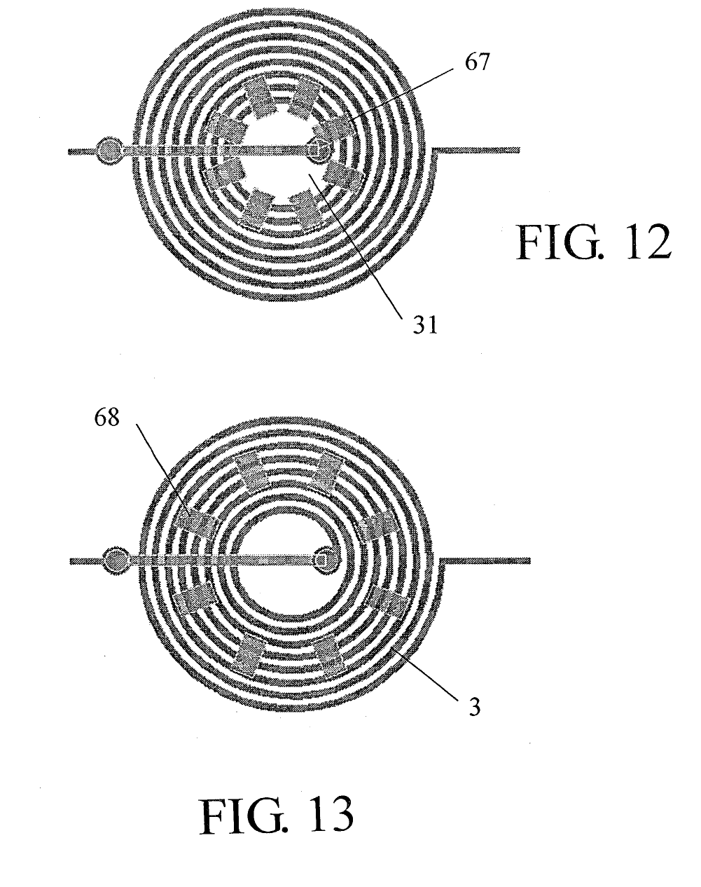

In the seventh embodiment shown in FIG. 12, a discrete metal layer pattern 67 is spread on the inner loop of the spiral inductor pattern 3 in an annular configuration, and the pattern 67 is partially extended to the center area 31 of the solenoidal inductor pattern 3.

In the eighth embodiment shown in FIG. 13, a discrete metal layer pattern 68 is spread on the middle portion between the outer and inner loops of the spiral inductor pattern 3.

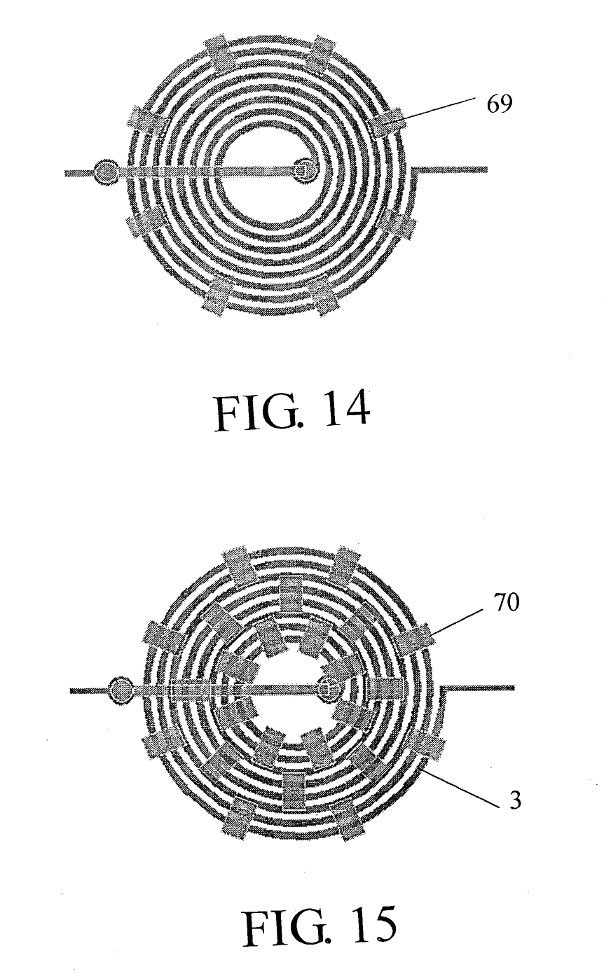

In the ninth embodiment shown in FIG. 14, a discrete metal layer pattern 69 is spread on the outer loop of the spiral inductor pattern 3 and is partially extended out of the pattern 3.

In the tenth embodiment shown in FIG. 15, a discrete metal layer pattern 70 is spread on the spiral inductor pattern 3 annularly in a multiple loops configuration.

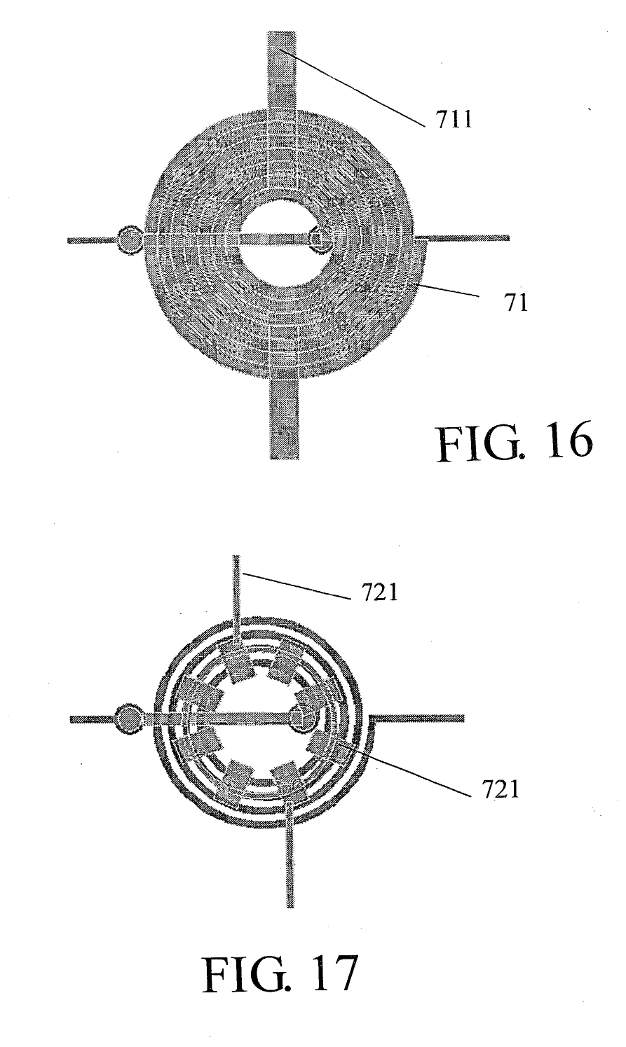

In the eleventh embodiment shown in FIG. 16, a continuous metal layer pattern 71 is shaded on the entire surface of the spiral inductor pattern 3 and is extended to connect with a grounding metal layer pattern 711 which is in connection with ground.

In the twelfth embodiment shown in FIG. 17, a discrete metal layer pattern 72 is spread on the spiral inductor pattern 3 in an annular configuration, and is extended to connect with a grounding metal layer pattern 721 which is in connection with the ground.

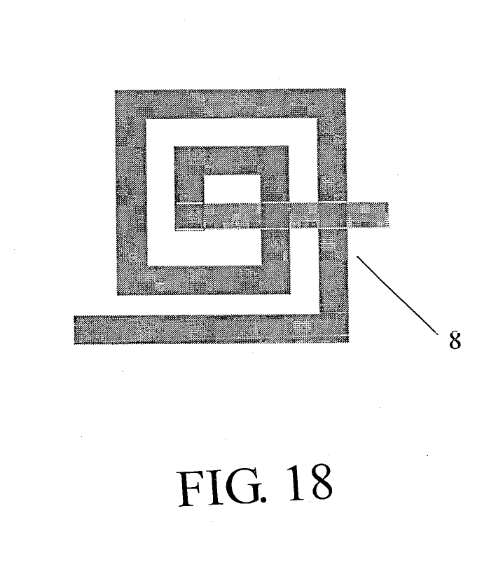

Above described inductors all belong to the round spiral inductors. Of course the shapes of the inductor may be formed into other convenient figures such as a square spiral inductor as shown in FIG. 18.

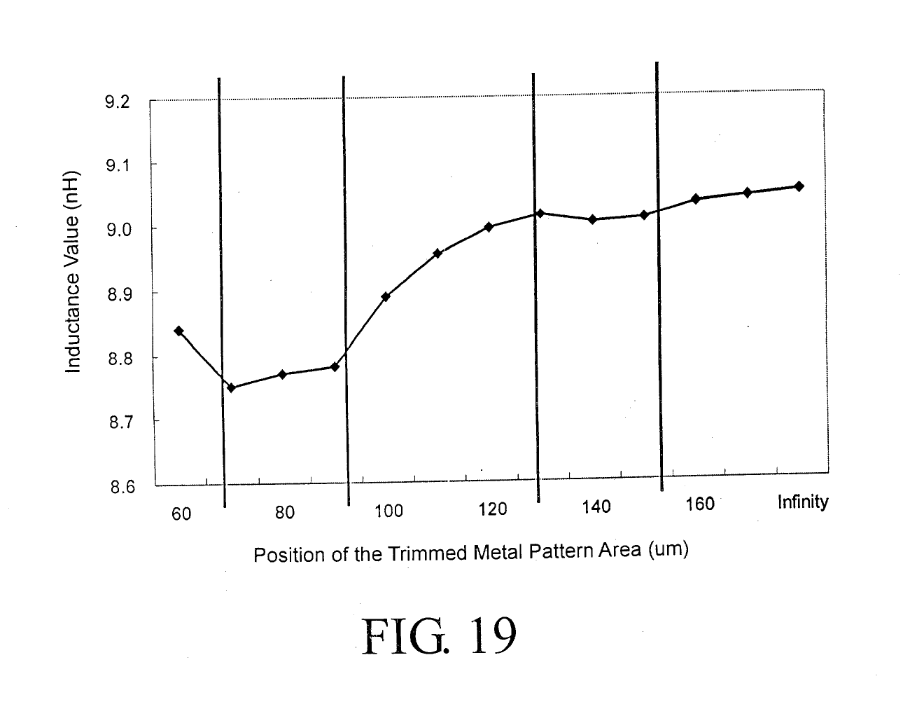

FIG. 19 is a graph showing the relative comparison of the measurement result between the trimming areas of the metal layer pattern and the inductance value (nH). In the figure, comparing STD, C1, C2, and C5, this can easily be observed that regardless of the value of the frequency, inductance value will always decrease with an increase in the size of the trimming areas of the metal layer pattern. In this way, specific positions of the metal pattern area are trimmed and adjusted so as to obtain an ideal inductance value. Moreover, according to test result, the metal layer pattern can be a circular, a square, or any geometrical figure. From the above-mentioned, this can be known that by means of the configuration of different metal pattern areas, this can always provide laser trimming and obtain an ideal inductance value with reference to the size of the trimming areas.

In this version, the method for inductor trimming of the integrated passive devices according to the present invention is really able to carry out wafer level trimming, on wafer measurement feedback and available for coarse and fine trimming with better process tolerance.

In all, the present invention is capable of performing laser trimming of inductance and on-wafer test by directly forming a dielectric layer on a spiral inductor, and forming a discrete or a continuous spirally coiled metal layer pattern above said dielectric layer. The position on the metal layer to be trimmed can be rapidly selected according to desired trimming range so as to compensate the process tolerance.

It is therefore to be understood that numerous variations and modifications may be made without departing from the true spirit and scope thereof as set forth in the following claims, and those are to be embraced in the present invention.

What is claimed is:

1. A method for trimming high frequency inductance of a passive component, wherein;
forming a first dielectric layer on an insulation substrate forming an inductor pattern on the upper surface of said first dielectric layer;
forming a second dielectric layer on said inductor pattern; and
forming a metal layer pattern on the upper surface of said second dielectric layer, leaving a space to said inductor pattern;
with this structure, adjustment of the inductance value can be easily performed by laser trimming said metal layer pattern.

2. The method as claimed in claim 1, wherein said dielectric layers are formed of a thick bisbenzocyclobutene (BCB) film.

3. The method as claimed in claim 1, wherein said dielectric layers are formed of a thick polyimide film.

4. The method as claimed in claim 1, wherein said dielectric layers are formed of photo-resist materials such as SU8, or SiO₂, Si₃N₄, and SiOₓN_{y}, or silicon glass materials such as phosphosilicate glass (PSG), borophosphosilicate glass (BPSG), fluorinated silicate glass (FSG), or other materials with low dielectric constant such as SiLK.

5. The method as claimed in claim 1, wherein said metal layer pattern is formed according to under bump metallization technique (UBM).

6. The method as claimed in claim 1, wherein said metal layer pattern is a continuous metal pattern.

7. The method as claimed in claim 6, wherein said continuous metal pattern shades the entire pattern of said inductor pattern.

8. The method as claimed in claim 6, wherein said continuous metal pattern shades the inner loop portion of said inductor pattern.

9. The method as claimed in claim 6, wherein said continuous metal pattern shades the outer loop portion of said spiral inductor pattern.

10. The method as claimed in claim 6, wherein said continuous metal pattern extends a grounding pattern to connect with the ground.

11. The method as claimed in claim 6, 7, 8, 9, or 10, wherein said continuous metal pattern shades along the portion between inner and outer loops of said spiral inductor pattern.

12. The method as claimed in claim 6, 7, 8, 9, or 10, wherein said continuous metal pattern shades along the conductor of said spiral inductor pattern.

13. The method as claimed in claim 1, wherein said metal layer pattern is formed into a discrete metal layer having a plurality of discrete blocks.

14. The method as claimed in claim 13, wherein said discrete metal layer pattern is formed annularly.

15. The method as claimed in claim 13, wherein said discrete metal-layer-pattern is formed into a spread configuration.

16. The method as claimed in claim 13, wherein said discrete metal layer pattern is radially spread.

17. The method as claimed in claim 13, 14, 15 or 16, wherein said discrete metal layer pattern is spread to discretely shade the inner loop portion of said spiral inductor pattern.

18. The method as claimed in claim 13, 14, 15 or 16, wherein said discrete metal layer pattern is spread to discretely shade the outer loop portion of said spiral inductor pattern.

19. The method as claimed in claim 13, 14, 15 or 16, wherein said discrete metal layer pattern layer is spread on said spiral inductor pattern in multiple loop configuration.

20. The method as claimed in claim 13, 14, 15 or 16, wherein said discrete metal layer pattern is partially shading the center area of said spiral inductor pattern.

21. The method as claimed in claim 13, 14, 15 or 16, wherein said discrete metal layer pattern is partially shading the outer loop portion of said spiral inductor pattern.

22. The method as claimed in claim 13, 14, 15 or 16, wherein said discrete metal layer pattern forms a continuous metal layer pattern at the area where no discrete metal layer pattern is formed.

23. The method as claimed in claim 13, 14, 15 or 16, wherein said discrete metal layer pattern is formed into a circular shape.

24. The method as claimed in claim 13, 14, 15 or 16, wherein said discrete metal layer pattern is formed into a square shape.

25. The method as claimed in claim 13, 14, 15 or 16, wherein said discrete metal layer pattern is formed into geometrical shape.
